(19) United States
(12) Patent Application Publication
(10) Pub. No.: US 2022/0077113 A1
(43) Pub. Date: Mar. 10, 2022

(54) 3D STACKED DIE PACKAGE WITH MOLDED INTEGRATED HEAT SPREADER

(71) Applicant: Intel Corporation, Santa Clara, CA (US)

(72) Inventors: Jenny Shio Yin ONG, Bayan Lepas Pulau (MY); Jackson Chung Peng KONG, Tanjung Tokong Pulau (MY); Bok Eng CHEAH, Gelugor Pulau (MY); Seok Ling LIM, Kulim Kedah (MY)

(21) Appl. No.: 17/089,741

(22) Filed: Nov. 5, 2020

(30) Foreign Application Priority Data
Sep. 4, 2020 (MY) PI2020004589

(51) Int. Cl. H01L 25/065; H01L 27/06; H01L 23/367; H01L 23/538; H01L 21/50

(52) U.S. Cl. CPC H01L 25/0657; H01L 27/0688; H01L 2021/60007; H01L 23/5384; H01L 21/50; H01L 23/367

(57) ABSTRACT

A chip package includes a substrate; a first chip including thermal VIAs, wherein the first chip is coupled to the substrate; a conductive frame at least partially surrounding the first chip and coupled to the substrate, wherein the first chip and the conductive frame have a height that is substantially the same, wherein an exposed substrate surface is covered in a layer of encapsulation material having the same height; a second chip positioned on a first portion the first chip surface in such a way to expose at least a portion of the first chip surface, wherein the at least one exposed portion includes thermal VIAs; and at least one conductive plate positioned on the at least one exposed portion, wherein the conductive plate is coupled to the conductive frame and the thermal VIAs of the first chip.

### CROSS-REFERENCE TO RELATED APPLICATIONS

This application claims priority to Malaysian Patent Application No. PI2020004589, filed on Sep. 4, 2020, which is incorporated by reference herein in its entirety.

### TECHNICAL FIELD

Various aspects relate generally to the field of semiconductor chip package manufacturing. More particularly devices and methods of creating devices for improved heat dissipation in a stacked chip package.

### BACKGROUND

3D stacked chip packages face challenges dissipating heat. For example, 3D stacked integrated circuit (IC) packages such as high bandwidth memory (HBM) may include the application of a thermal interface material (TIM) between stacked chips and/or cavities between dies for lateral heat path dissipation. Because stacked chip packages may have a longer heat dissipation paths, reducing the heat dissipation path is desirable for robust thermal dissipation and device reliability.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. It should be understood that the drawings are diagrammatic and schematic representations of exemplary aspects of the invention, and are neither limitative nor necessarily drawn to scale of the present invention.

In the following description, various aspects of the invention are described with reference to the following drawings, in which:

FIG. 1A shows an exemplary molded integrated heat spreader in a stacked chip package according to some aspects;

FIG. 1B shows an exemplary top view of a layer of a molded integrated heat spreader in a stacked chip package according to some aspects;

FIG. 1C shows an exemplary top view of a layer of a molded integrated heat spreader in a stacked chip package according to some aspects;

FIG. 2 shows an exemplary top view of a layer of a molded integrated heat spreader in a stacked chip package according to some aspects;

FIGS. 3A-3F show an exemplary method of manufacturing a molded integrated heat spreader in a stacked chip package according to some aspects.

FIGS. 4A-4J show an exemplary method of manufacturing a molded integrated heat spreader in a stacked chip package according to some aspects.

FIG. 5 shows a flow chart illustrating an exemplary method of manufacturing a molded integrated heat spreader in a stacked chip package according to some aspects.

### DESCRIPTION

The following detailed description refers to the accompanying drawings that show, by way of illustration, specific details and aspects of aspects in which the aspects of this disclosure are practiced.

The word “exemplary” is used herein to mean “serving as an example, instance, or illustration.” The words “plurality” and “multiple” in the description and claims refer to a quantity greater than one. The terms “group,” “set”, “sequence,” and the like refer to a quantity equal to or greater than one. Any term expressed in plural form that does not expressly state “plurality” or “multiple” similarly refers to a quantity equal to or greater than one. The term “lesser subset” refers to a subset of a set that contains less than all elements of the set. Any vector and/or matrix notation utilized herein is exemplary in nature and is employed for purposes of explanation. Aspects of this disclosure described with vector and/or matrix notation are not limited to being implemented with vectors and/or matrices and the associated processes and computations may be performed in an equivalent manner with sets or sequences of data or other information.

The term chips (also referred to herein as “silicon dies”) are generally “packaged” prior to shipping and merging with other electronics packages. This packaging typically involves encapsulating the chips in a material and providing electrical contacts on the outside of the housing to provide an interface for the chip. Among other things, chip packaging can provide protection against impurities, provide mechanical support, dissipate heat and reduce thermo-mechanical stress.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Although a silicon die may refer to a processor chip, a radio-frequency (RF) chip, an integrated passive device (IPD) chip, or a memory chip may be mentioned in the same sentence, but it should not be construed that they are equivalent structures. The appearance of the phrase “aspect” various places throughout this disclosure are not necessarily all referring to the same aspect. Furthermore, the particular features, structures, or characteristics may be combined in any suitable manner in one or more aspects.

Various features are grouped together for the purpose of streamlining the disclosure. This method of disclosure is not to be interpreted as reflecting an intention that the claims require more features than are expressly recited in each claim. Rather, as the following claims reflect, inventive subject matter lies in less than all features of a single disclosed aspect. Thus, the following claims are hereby incorporated into the Detailed Description, with each claim standing on its own as a separate aspect.

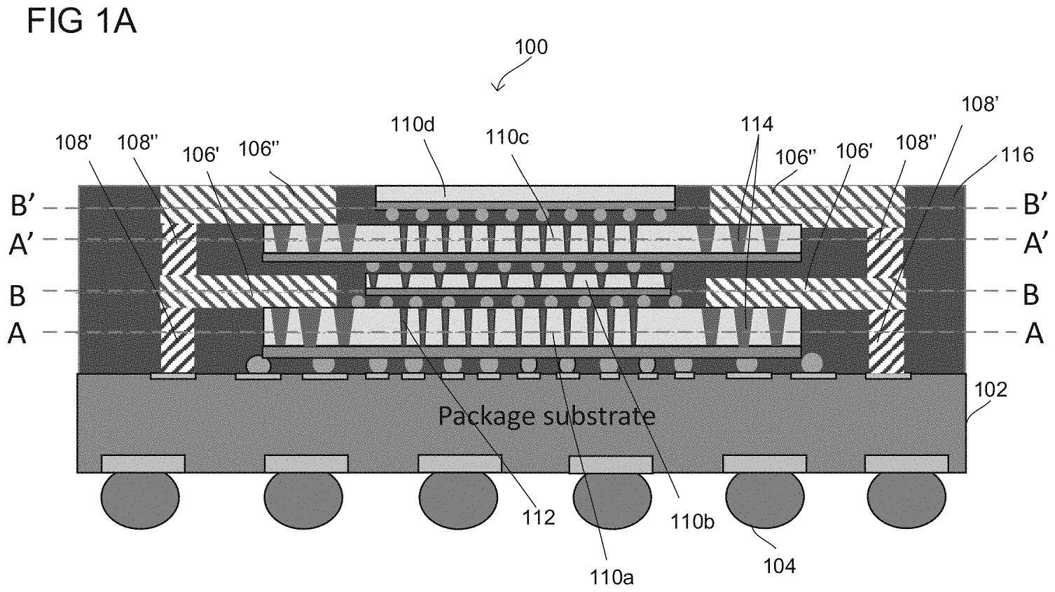

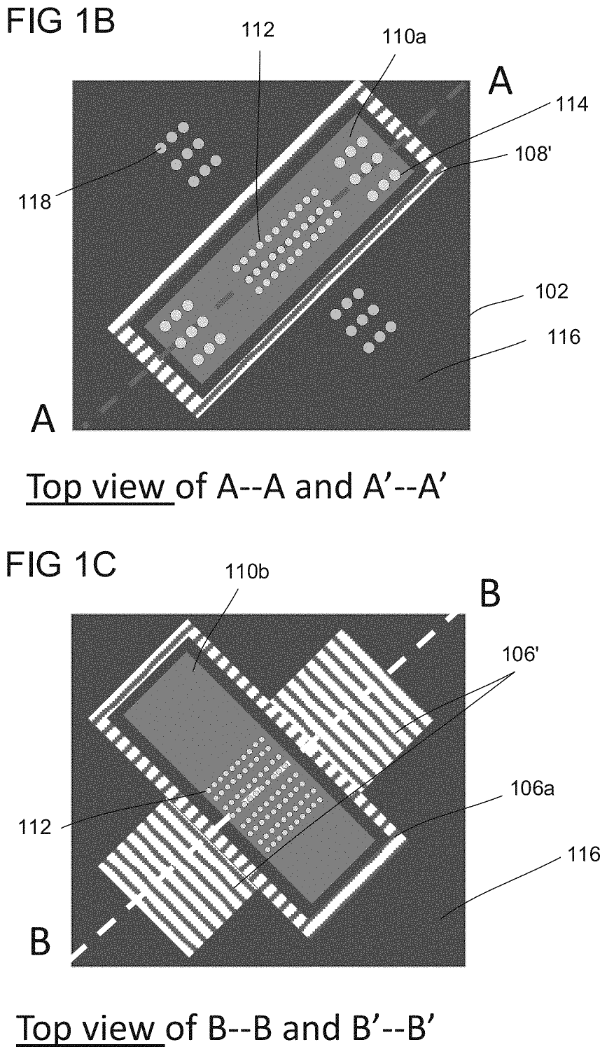

FIG. 1A illustrates a stacked chip package 100 according to some aspects. Chip package 100 includes stacked chips 110a, 110b, 110c and 110d. The stacked chips 110a, 110b, 110c and 110d may be coupled to each other or to package substrate 102. For example, the chips 110a, 110b, 110c and 110d may be connected to each other or package substrate 102 through solder bumps. Chips 110a-d may include a plurality of through silicon VIAs (TSV) 112 and a plurality of thermal TSVs 114. Chip package 100 may include conductive frames 108′ and 108″ which encircle at least one of the stacked chips 110a-d, for example, frames 108′ and 108″ encircle chips 110a and 110c respectively as shown in FIG. 1A. Chip package 100 may also include conductive plates 106′ and 106″. Conductive plates 106′ and 106″ may be connected to thermal TSVs 114 to dissipate heat. The chips 110a-d, conductive frames 108, and conductive plates 106 are encapsulated in molding material 116. For example, a first chip 110a may be coupled to substrate 102 and encircled by frame 108′ which is also couple to substrate 102. A second chip 110b may be place on the top surface of first chip 110a in a perpendicular position as to leave some of the surface of first chip 110a exposed. Conductive plates 106′ may be coupled to thermal TSVs 114 of the exposed surface of first chip 110a. Chips may continue to be stacked by placing a conductive frame 108″ around third chip 110c and continuing to place subsequent chip (e.g., a fourth chip 110d) perpendicular to the third chip 110c and coupling conductive plates 106″ to thermal TSVs 114.

FIGS. 1B and 1C illustrate a top view of a layer of stacked chip package 100. FIG. 1B illustrates a layer of chip package 100 including a first chip 110a encircled by conductive frame 108′. For example, chip 110a and conductive frame 108′ may be coupled to substrate 102 or to another chip 110.

FIG. 1C illustrates a second layer of chip package 100. For example, a layer directly on top of the layer illustrated in FIG. 1B. A second chip 110b may be position directly on top of and perpendicular to first chip 110a from the previous layer. Positioning chips in perpendicularly leaves an exposed surface of the bottom chip. Conductive plates 106′ may be coupled to the exposed surface of chip 110 of the previous layer. For example, coupled to thermal TSVs 114 of first chip 110a of the previous layer. Conductive plates 106 may include an extended conductive plate 106a encircles the second chip 110b. Second chip 110b may be coupled to the package substrate 102 through a plurality of through mold vias (TMVs) 118 shown in FIG. 1B.

FIG. 2 illustrates a top view of semiconductor chip package 200 including a plurality of passive components. Chip package 200 is similar to the package described in FIGS. 1A-1C. Chip package 200 includes at least two chips 110 stacked perpendicularly. An upper conductive frame 108″ (not shown) encircles the third chip 110c (not shown) (See FIG. 1A). Upper conductive plates 106″ are coupled to upper conductive frame 108″ and third chip 110c. For example, conductive plates 106″ may be coupled to thermal TSVs 114 (not shown) of third chip 110c. Fourth chip 110d and upper conductive plates 106″ are placed directly on top of and in a perpendicular position relative to third chip 110c. Upper conductive plates 106″ may be extended to at least partially encircle the fourth chip 110b. Fourth chip 110d and upper conductive plates 106″ may be coupled to a thermal interface layer, an integrated heat spreader and/or cooling fan (not shown) to dissipate heat. Spaces between chips 110, conductive frames 108, and conductive plates 106 may be filled with molding material 116. Chip package 200 may also include integrated voltage regulator 202, power management module 204, and decoupling capacitors 206. Voltage regulator 202, power management module 204, and decoupling capacitors 206 may be disposed on package substrate 102 and coupled to the chips 110 through VIAs and routing not shown in FIG. 2. For example, a thermal dissipating passive component such as voltage regulator 202, power management module 204 and/or capacitors 206 attached adjacent and/or closer to chips 110 within stacked chip package 200 may result in improved electrical performance through a reduced AC inductance loop.

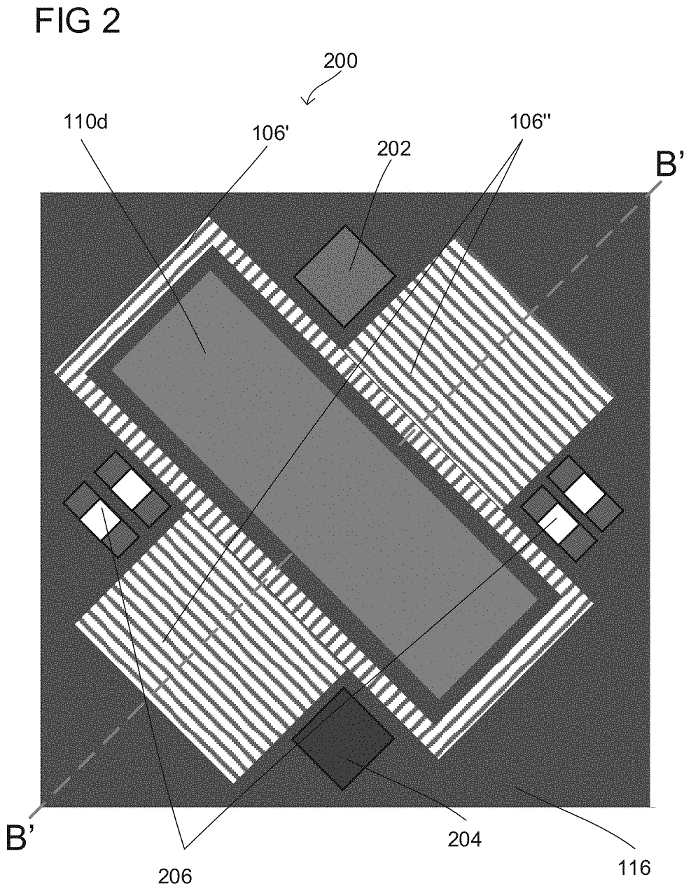

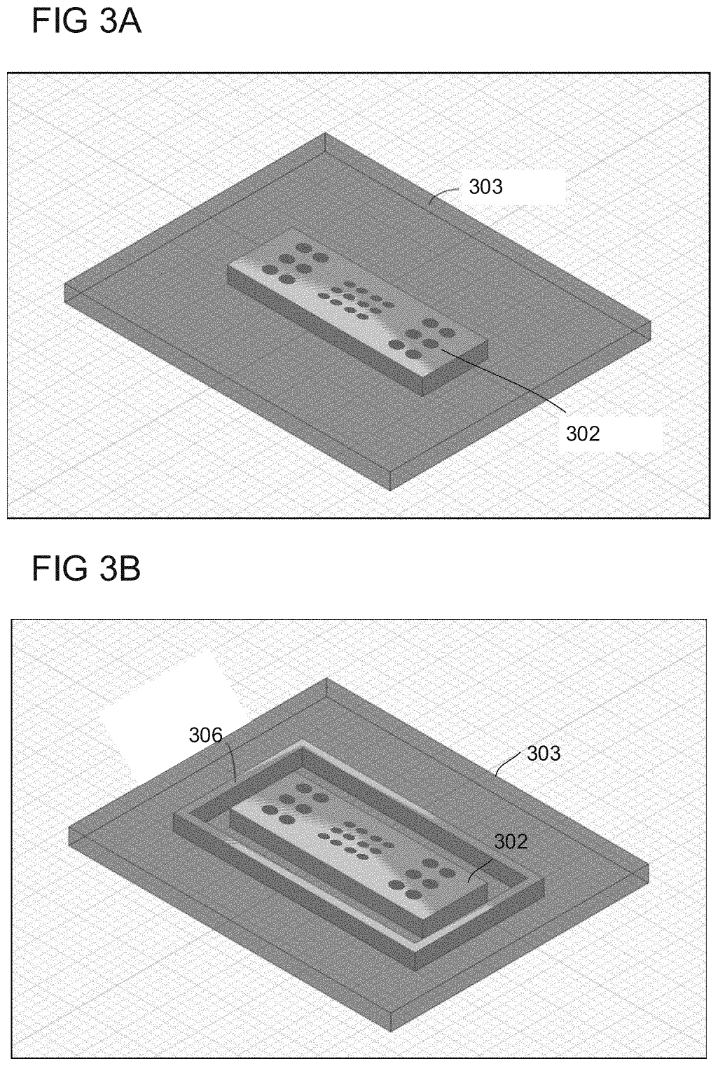

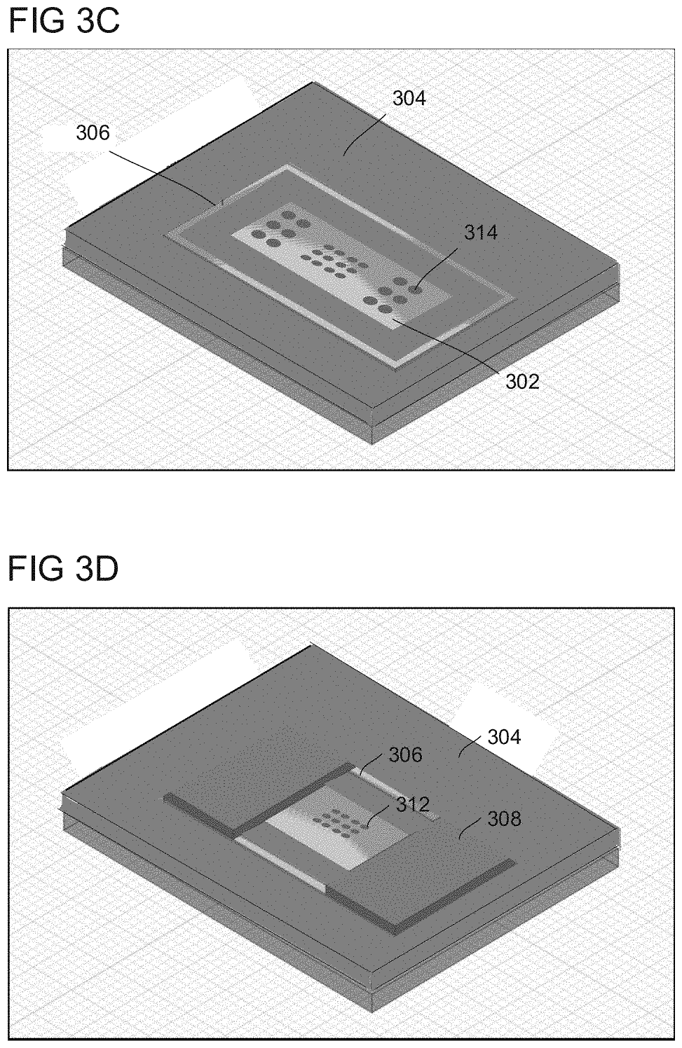

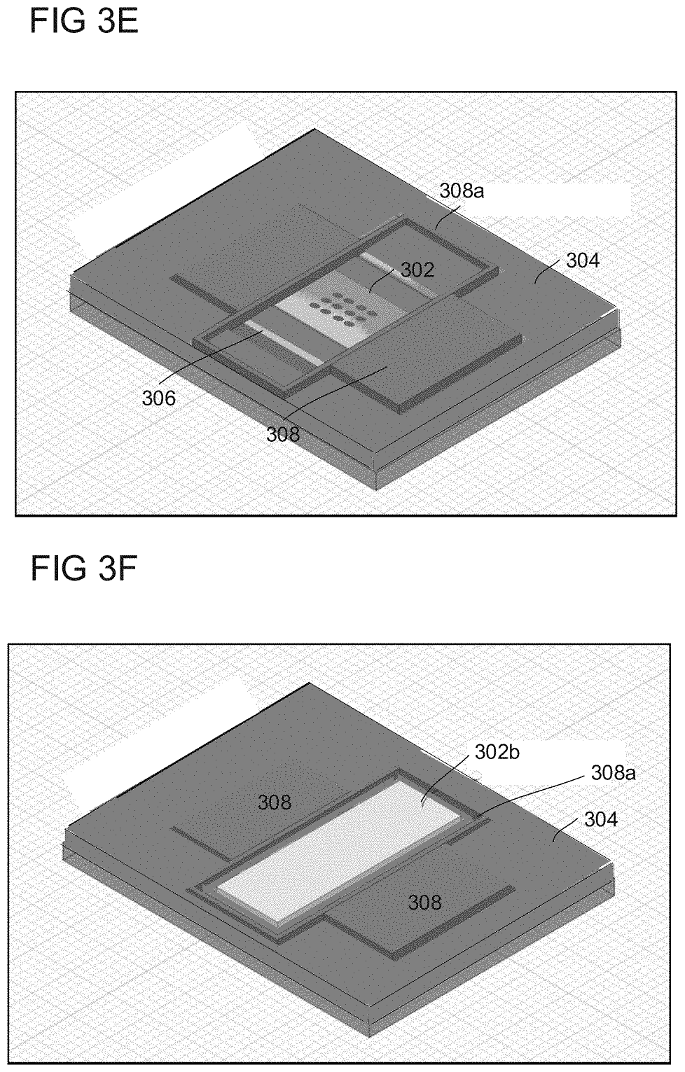

FIGS. 3A-3F illustrate a perspective view of a method of a forming a molded integrated heat spreader in a stacked chip package. FIG. 3A illustrates chip 302 positioned on a package substrate 303, for example, through a solder reflow process or a thermal compression bonding process. FIG. 3B illustrates conductive frame 306 positioned around chip 302 on package substrate 303. For example, attached a preformed metal frame e.g., a copper or aluminum frame on package substrate 303. FIG. 3C illustrates chip 302 and conductive frame 306 positioned on package substrate 303 being surrounded by molding material 304. For example, molding material 304 may be disposed over the chip 302, substrate 303 and conductive frame 306 using a compression or an injection molding process. The top surface of chip 302 and conductive frame 306 are left exposed by the molding and/or surface polishing process. TSVs 314 on the surface of chip 302 are also left exposed. Alternatively, conductive frame 306 may be formed around chip 302 on package substrate 303 after the molding process. For example, an etching process may be used to cut carve out space for frame 306 in molding material 304 followed by solder paste printing or electroplating process. FIG. 3D illustrates conductive plates 308 positioned on conductive frame 306 and chip 302. Conductive plates 308 are positioned to leave an exposed portion of the top surface of chip 302. Conductive plates 308 may be connected to thermal TSVs 314 (shown in FIG. 3C) of chip 302. FIG. 3E illustrates extended conductive plates 308a being positioned on the molding material 304, projecting a footprint for second chip 302b. The extended conductive plates 308a maybe be coupled to the first conductive frame 306, conductive plates 308, and chip 302. FIG. 3F illustrates a second chip 302b positioned directly on top of the first chip 302a and within conductive plates 308 and extended conductive plate 308a. Second chip 302b may be electrically coupled to the first chip 302a and the first frame 306. Additionally, a second molding process may be applied after positioning second chip 302.

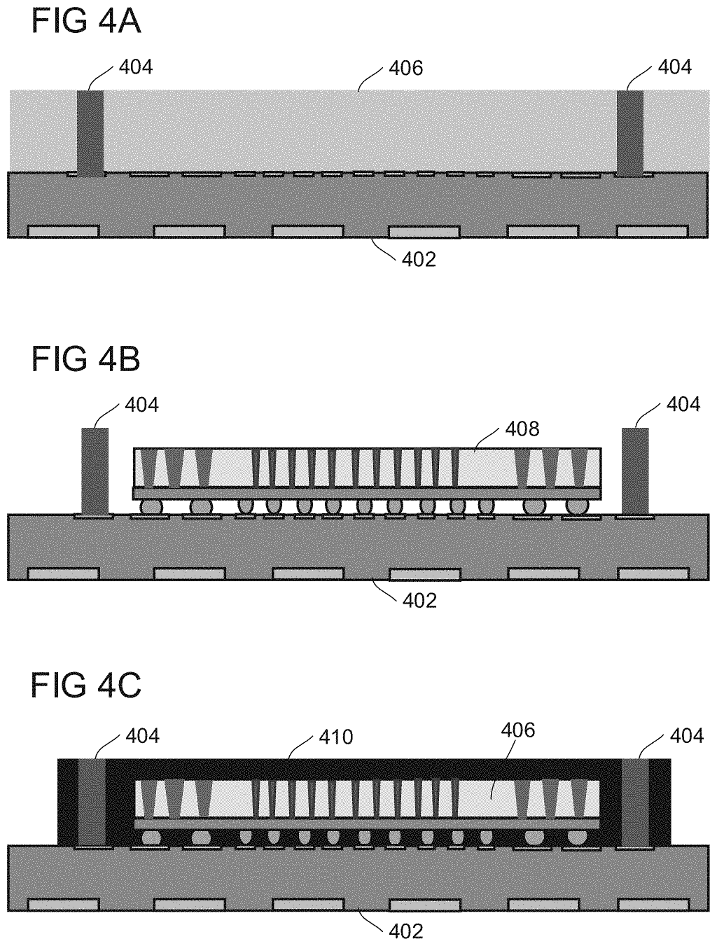

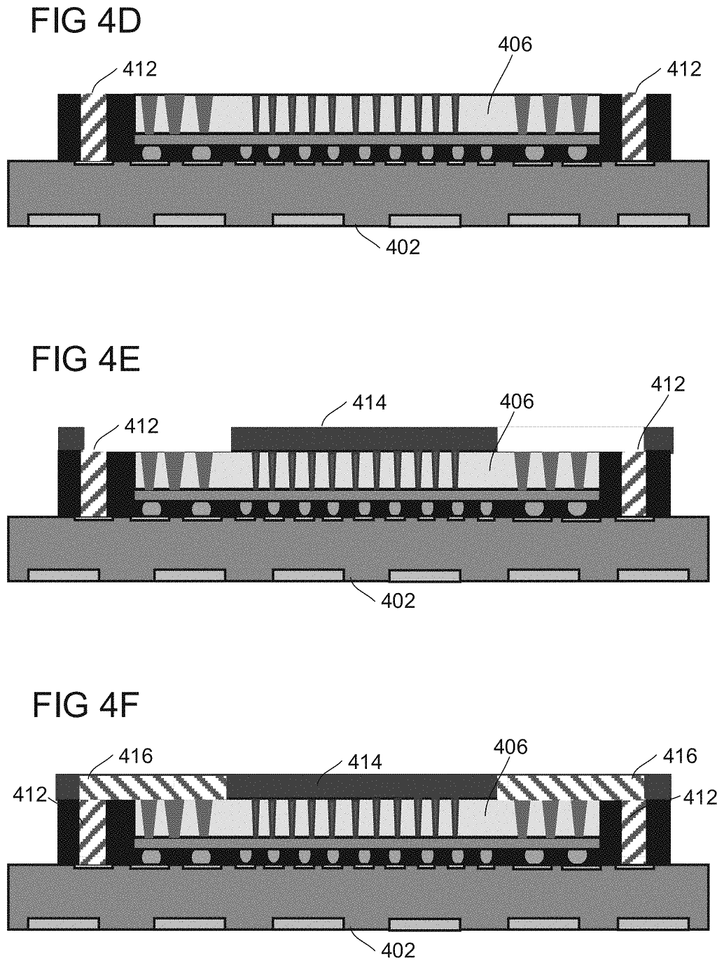

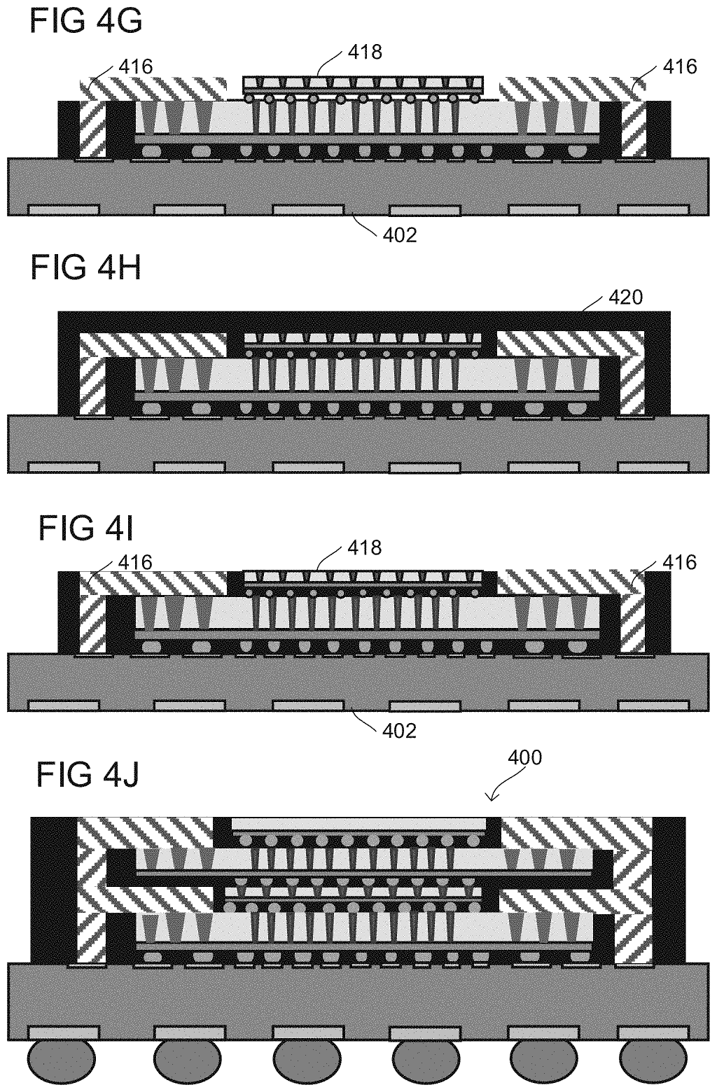

FIGS. 4A-4J illustrate a cross section view of a method of forming a molded integrated heat spreader in a stacked chip package. FIG. 4A illustrates disposing a dry film resist (DFR) layer 406 over package substrate 402. Portions of DFR layer 406 are developed 404 to define space for a conductive frame. For example, DFR may be disposed and developed using a lamination, photolithography development, or etching process. FIG. 4B illustrates the removal of undeveloped DFR layer 406 and positioning chip 408 within developed DFR layer 404 and electrically coupled to package substrate 402. For example, attaching chip 408 to substrate 402 using solder reflow or thermal compression bonding processes. FIG. 4C disposing a molding material 410 over chip 406 and up to developed DFR 404. FIG. 4D illustrates planarization of molding material 410 to expose a top surface of chip 406 and developed DFR 404. Additionally, replacing developed DFR 404 with conductive frame 412 positioned to encircle chip 406 through, for example, an electroplating process or a solder paste printing process. Molding material 410 may be planarized using a mechanical grinding process. FIG. 4E illustrates disposing and developing a second DFR 414 over the chip package of FIG. 4D. Removing the undeveloped DFR layer to expose thermal TSVs of chip 406. For example, the second DFR 414 may be disposed directly over chip 406, conductive frame 412, and mold layer 410 using lamination, photolithography development, or etching process. FIG. 4F illustrates forming conductive plates 416 over exposed surface of chip 406. Conductive plates 416 may be coupled to thermal TSVs of chip 406. For example, forming conductive plates 416 using a paste printing or electroplating process. FIG. 4G. illustrates removing developed DFR layer 414 and attaching a second chip 418 to first chip 406. For example, removing developed DFR 414 using an etching process and attaching chip 418 using a reflow or thermal compression bonding process. FIG. 4H illustrates disposing a second molding material layer 420 over conductive plates 416 and chip 418. For example, disposing the molding layer 420 using a compression, injection, or transfer molding process. FIG. 4I illustrates planarization of molding material layer 420 to expose a top surface of chip 418 and conductive plates 416. For example, removing part of molding layer 420 using a mechanical grinding process. FIG. 4J illustrates a stacked chip package 400 with four stacked chips using the steps outlined in FIGS. 4A-4I.

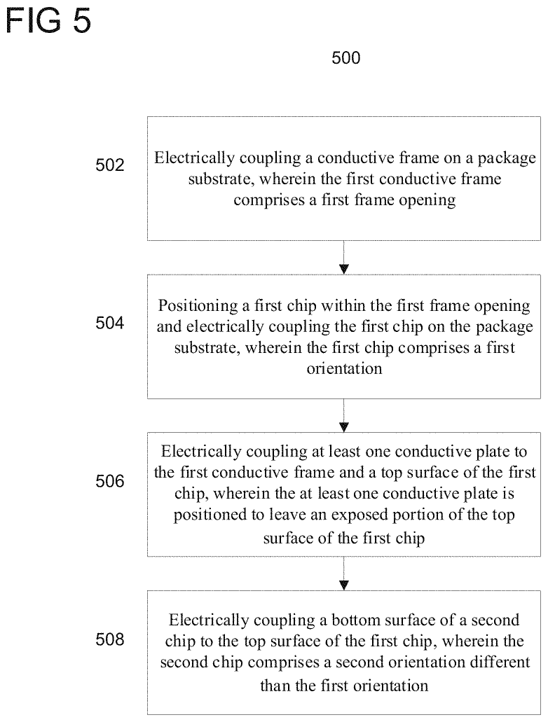

FIG. 5 shows a flow chart illustrating an exemplary method 500 of method of manufacturing a stacked chip package according to some aspects. As shown in FIG. 5, method 500 includes electrically coupling a conductive frame on a package substrate, wherein the first conductive frame comprises a first frame opening (502), positioning a first chip within the first frame opening and electrically coupling the first chip on the package substrate, wherein the first chip comprises a first orientation (504), electrically coupling at least one conductive plate to the first conductive frame and a top surface of the first chip, wherein the at least one conductive plate is positioned to leave an exposed portion of the top surface of the first chip (506), and electrically coupling a bottom surface of a second chip to the top surface of the first chip, wherein the second chip comprises a second orientation different than the first orientation (508).

Integrating a molded heat spreader in a stacked chip package improves thermal dissipation. For example, in a 3D stacked integrated circuit package including a molded integrated heat spreader may shorten the heat dissipation path. Stacking chips perpendicular to each other allows for shorter heat dissipation paths. Each chip of stacked chip package is surrounded by a conductive frame. For example, a chip and conductive frame may be coupled to a package substrate. The conductive frame encircles the chip. A conductive plate may be coupled directly on top of the conductive frame and the chip. For example, the conductive plates may be coupled to thermal VIAs of the chip. The conductive plates may not be coupled to any other chips and used to dissipate heat. Gaps between elements such as frames, plates, and chips may be filled with an encapsulation or molding material. The conductive frame and the conductive plates form a container over the chip with an opening at the top between two conductive plates. The conductive frame is not in direct contact with the chip. The two conductive plates are in direct contact with a top surface of both the conductive frame and the chip.

The conductive plates form a conductive plane directly over the first frame and the first chip as previously described. The conductive plates include a gap or opening to expose a surface of the first chip so that a second chip may be coupled to the first chip in the opening. The second chip is perpendicularly positioned directly over the first chip. Conductive plate may be extended to at least partially encircle the second chip. A second conductive frame is directly coupled to conductive plates. A second pair of conductive plates are directly coupled to the second conductive frame and a third chip in much the same way as the first conductive plates are attached to the first conductive frame and the first chip. The second conductive plates may at least partially encircle a fourth chip disposed on the third chip.

For example, the conductive frame may be coupled to the package substrate. The chip may be couple to the package substrate within the conductive frame so that the conductive frame encircles a periphery of the chip. The bottom surface of the conductive frame and the bottom surface of the chip are coupled to the package substrate. A pair of conductive plates are in direct contact with a portion of the top surface of the conductive frame and a portion of the top surface of the chip. The conductive plates are in a plane over the conductive frame and chip. The conductive plates may extend across the conductive frame and the chip in such a way that a portion of the top surface of the conductive frame and a portion of the top surface of the chip are exposed. A subsequent chip may be positioned on the exposed top surface of the conductive frame and the chip. The subsequent chip may be at least partially encircled by the conductive frame. The subsequent chip may be electrically coupled to the conductive frame and the chip. The subsequent chip may be oriented in a different direction than the first chip. For example, the subsequent chip may be oriented perpendicular relative to the chip. The conductive plate may be extended and positioned directly on the conductive frame and the chip in such a way to encircle the subsequent chip.

A stacked chip package configured with alternating chips positioned orthogonally relative to each other may improve heat flow and/or thermal dissipation in a device. Heat spreaders including conductive frames and conductive plates may surround chips and span across chips, such as silicon dies, and connected to the thermal interface of a chip. An Integrated molded heat spreader may include vertically stacked heat spreaders corresponding to vertically stacked chips.

An integrated molded heat spreader provides efficient thermal dissipation. Efficient thermal dissipation allows device miniaturization and/or performance improvements as compared to conventional 3D die-stacked packages which limit the number of stacked dies due to thermal dissipation deficiency. The integrated molded heat spreader allows for an increased 3D die stacking hierarchy because of its efficient thermal dissipation.

Additionally, an integrated molded heat spreader may provide improved electrical performance, such as signal and power integrity. Noise shielding, for example, electromagnetic and/or radio frequency interferences and power decoupling may be integrated as part of the solution. For example, the integrated molded heat spreader may be coupled to a reference voltage e.g., a ground reference voltage (Vss) from the package substrate and/or chips through the conductive frames and the conductive plates for noise shielding. In an aspect, an on-package voltage regulator may be included adjacent to the stacked configuration as previously described. This solution may also include decoupling capacitors and a power management module.

The molded integrated heat spreader for improved thermal dissipation may include a mold substrate. For example, the mold substrate may comprise one or more polymer layers including epoxy resins and/or silicon composites.

The stacked chip package may include several different types of chips. For example, the chip package may include 4 different chips. Chips may include a top surface and a bottom surface where the top and bottom surface are opposite sides of the chip. For example, a first stacked chip may be a central processing unit (CPU) or a platform controller hub (PCH). The first stacked chip may include a plurality of through silicon VIAs (TSVs) at least partially extending through a bottom surface and a top surface of the first stacked chip. The TSVs facilitate data signal transmission, power supply, and/or ground reference voltage connections. The first stacked chip may be coupled to the package substrate through its bottom surface. The first conductive frame encircling the first stacked chip may be made of a copper layer, tin-silver (SnAg) solder composites, or nano particle composites. For example, carbon nano-tube composites may encircle a periphery of the first stacked chip. The first conductive frame is spaced apart from the first stacked chip by the mold layer. For example, the spacing between the first conductive frame and the first stacked chip may range from 100 μm to approximately 2 mm. The first set of conductive plates may be seated on the first conductive frame and extends across a portion of the top surface of the first stacked chip. The conductive plates may be in direct contact with thermal TSVs of the chip to facilitate thermal dissipation away from the chip. Alternatively, the thermal TSVs may not be in physical contact with a metal redistribution layer (RDL) coupled to the bottom surface of the first stacked chip.

A second stacked chip may be one of several different types of chips. For example, the second stacked chip may be a memory device. The second stacked chip may include top and bottom surfaces. The bottom surface of the second stacked chip may be coupled to TSVs of the top surface of the first stacked chip. The second stacked chip may be oriented in a perpendicular direction relative to the orientation of the first stacked chip. The conductive plates connected to the first stacked chip and the first conductive frame may partially encircle a periphery of the second stacked chip. The first set of conductive plates may be separated from the second stacked chip by the mold layer. For example, the spacing between the first conductive plates and the second stacked chip may range from 25 μm to approximately 2 mm. The second stacked chip may include a plurality of through silicon VIAs (TSVs) at least partially extending through the top and bottom surfaces to facilitate data signal transmission, power supply, and/or ground reference voltage connections.

A third stacked chip may be one of several different types of chips. For example, the third stacked chip may be a memory device. The third stacked chip may include top and bottom surfaces. The bottom surface of the third stacked chip may be coupled to TSVs of the top surface of the second stacked chip. The third stacked chip may be oriented in a different direction than that of the second stacked chip. For example, the third stacked chip may be oriented in parallel direction as that of the first stacked chip. The third stacked chip may include a plurality of through silicon VIAs (TSVs) at least partially extending through the top and bottom surfaces to facilitate data signal transmission, power supply, and/or ground reference voltage connections. The second conductive frame can be made of multiple materials. For example, the frame may be made of a copper layer, tin-silver (SnAg) solder composites, or nano particle composites. For example, carbon nano-tube composites. For example, the frame may be coupled to the second set of conductive plates and encircle a periphery of the third stacked chip. The second conductive frame is spaced apart from the third stacked chip by the mold layer. For example, the spacing between the second conductive frame and the third stacked chip may range from 25 μm to approximately 2 mm. The second set of conductive plates seated on the second conductive frame and extend across a portion of the top surface of the third stacked chip. The second set of conductive plates may be in contact with TSVs of the top surface of the third stacked chip to facilitate thermal dissipation away from the third stacked chip. Some TSVs may not be in physical contact with a metal redistribution layer (RDL) coupled to the bottom surface of the third stacked chip.

A fourth stacked chip may be one of several different types of chips. For example, the fourth stacked chip may be a memory device. The fourth stacked chip includes a top surface and a bottom surface. The bottom surface of the fourth stacked chip is coupled to TSVs of the top surface of the third stacked chip. The fourth stacked chip may be position in a similar direction as the second stacked chip. For example, the direction of the fourth stacked chip may be parallel to the direction of the second stacked chip. The second set of conductive plates may partially encircle a periphery of the fourth stacked chip. The second set of conductive plates may include an extended conductive plate encircles the fourth stacked chip. The second set of conductive plates may be spaced apart from the fourth stacked chip by the mold layer. For example, the spacing between the second set of conductive plates and the fourth stacked chip may range from 25 μm to approximately 2 mm. The second set of conductive plates are planar to the top surface of the fourth stacked chip, and in contact with thermal interface layer of a system heat sink and/or cooling fan and/or heat-pipe for thermal dissipation.

A stacked chip package including a molded integrated heat spreader may be coupled to a ground reference voltage or a power supply voltage through package substrate contact pads and metal routing for electromagnetic noise shielding. For example, the chip package may be coupled to a ground reference voltage (Vss) or a power supply reference voltage (Vcc) source from a motherboard or a printed circuit board. The device may further include passive components such as decoupling capacitors. Additionally, the device may include a voltage regulator and a power management module adjacent to stacked chips for improved electrical performance through a reduced AC inductance loop.

While the above descriptions and connected figures may depict electronic device components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

The following examples disclose various aspects of this disclosure:

Example 1 is a chip package including a substrate including a substrate surface; a first chip including a first chip surface and a plurality of thermal vias, wherein the first chip is coupled to the substrate; a conductive frame at least partially surrounding the first chip, wherein the conductive frame is coupled to the substrate, wherein the first chip and the conductive frame have a height that is substantially the same, wherein a remainder of the substrate surface is covered in a layer of encapsulation material having the same height as the first chip and the conductive frame; a second chip positioned on a first portion of the first chip surface, wherein the second chip is positioned to expose at least one exposed portion of the first chip surface, wherein the at least one exposed portion comprises at least one of the plurality of thermal vias; and at least one conductive plate positioned on the at least one exposed portion, wherein the conductive plate is coupled to the conductive frame and the at least one of the plurality of thermal vias.

In Example 2, the subject matter of Example 1 can optionally further include wherein the conductive frame comprises a copper layer.

In Example 3, the subject matter of Examples 1 or 2 wherein the conductive frame comprises a plurality of tin-silver (SnAg) solder composites.

In Example 4, the subject matter of Examples 1 to 3 can optionally further include wherein the conductive frame comprises a plurality of nano particle composites.

In Example 5, the subject matter of Examples 1 to 4 can optionally further include wherein the plurality of nano particle composites comprise carbon nano tube composites.

In Example 6, the subject matter of Examples 1 to 5 can optionally further include wherein the conductive frame comprises a distance from the first chip.

In Example 7, the subject matter of Examples 1 to 6 can optionally further include wherein the distance from the first chip comprises a range from 100 μm to approximately 2 mm.

In Example 8, the subject matter of Examples 1 to 7 can optionally further include wherein the at least one conductive plate comprises a distance from the second chip.

In Example 9, the subject matter of Examples 1 to 8 can optionally further include wherein the distance from the second chip comprises a range from 25 μm to approximately 2 mm.

In Example 10, the subject matter of Examples 1 to 9 can optionally further include wherein the second chip is positioned perpendicular relative to the first chip.

Example 11 is a method of forming a chip package including: electrically coupling a first conductive frame on a package substrate, wherein the first conductive frame includes a first frame opening; positioning a first chip within the first frame opening and electrically coupling the first chip on the package substrate, wherein the first chip comprises a first orientation; electrically coupling at least one conductive plate to the first conductive frame and a top surface of the first chip, wherein the at least one conductive plate is positioned to leave an exposed portion of the top surface of the first chip; and electrically coupling a bottom surface of a second chip to the top surface of the first chip, wherein the second chip comprises a second orientation different than the first orientation.

In Example 12, the subject matter of Example 11 can optionally further include wherein the conductive frame comprises a copper layer.

In Example 13, the subject matter of Examples 11 and 12 can optionally further include wherein the conductive frame comprises a plurality of tin-silver (SnAg) solder composites.

In Example 14, the subject matter of Examples 11 to 13 can optionally further include wherein the conductive frame comprises a plurality of nano particle composites.

In Example 15, the subject matter of Examples 11 to 14 can optionally further include wherein the plurality of nano particle composites comprise carbon nano tube composites.

In Example 16, the subject matter of Examples 11 to 15 can optionally further include wherein the conductive frame comprises a distance from the first chip.

In Example 17, the subject matter of Examples 11 to 16 can optionally further include wherein the distance from the first chip comprises a range from 100 μm to approximately 2 mm.

In Example 18, the subject matter of Examples 11 to 17 can optionally further include wherein the at least one conductive plate comprises a distance from the second chip.

In Example 19, the subject matter of Examples 11 to 18 can optionally further include wherein the distance from the second chip comprises a range from 25 μm to approximately 2 mm.

In Example 20, the subject matter of Examples 11 to 19 can optionally further include wherein the second chip is positioned perpendicular relative to the first chip.

Example 21 is a method of forming a chip package including: depositing a first dry film resist layer on a package substrate; developing the first dry film resist layer to form a first frame space; removing an undeveloped portion of the first dry film resist layer; electronically coupling a first chip to the package substrate, wherein the first die is positioned within the first frame space and oriented in a first direction; depositing a mold layer over the first frame space and the first chip; removing excess mold layer to expose the a top surface of the first frame space and a top surface of the first chip; replacing the developed first dry film resist from the frame space; forming a conductive frame within the frame space; depositing a second dry film resist layer over a top surface of the chip package; developing the second dry film resist layer to form at least one conductive plate space; removing an undeveloped portion of the second dry film resist layer to create a conductive plate space; forming at least one conductive plate space in the at least one conductive plate space, wherein the least one conductive plate space spans over the conductive frame and a portion of the top surface of the first chip; and electronically coupling a second chip to an exposed surface of the first chip, wherein the first second chip is oriented in a second direction.

In Example 22, the subject matter of Example 21 can optionally further include wherein the conductive frame comprises a copper layer.

In Example 23, the subject matter of Examples 21 and 22 can optionally further include wherein the conductive frame comprises a plurality of tin-silver (SnAg) solder composites.

In Example 24, the subject matter of Examples 21 to 23 can optionally further include wherein the conductive frame comprises a plurality of nano particle composites.

In Example 25, the subject matter of Examples 21 to 24 can optionally further include wherein the plurality of nano particle composites comprise carbon nano tube composites.

In Example 26, the subject matter of Examples 21 to 25 can optionally further include wherein the conductive frame comprises a distance from the first chip.

In Example 27, the subject matter of Examples 21 to 26 can optionally further include wherein the distance from the first chip comprises a range from 100 μm to approximately 2 mm.

In Example 28, the subject matter of Examples 21 to 27 can optionally further include wherein the at least one conductive plate comprises a distance from the second chip.

In Example 29, the subject matter of Examples 21 to 28 can optionally further include wherein the distance from the second chip comprises a range from 25 μm to approximately 2 mm.

In Example 30, the subject matter of Examples 31 to 29 can optionally further include wherein the second chip is positioned perpendicular relative to the first chip.

Example 31 is a non-transitory computer readable medium storing instructions that, when executed by one or more processors of a communication device, cause the communication device to perform the method of any one of Examples 11 to 30.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip package comprising:
a substrate comprising a substrate surface;
a first chip comprising a first chip surface and a plurality of thermal vias, wherein the first chip is coupled to the substrate;
a conductive frame at least partially surrounding the first chip, wherein the conductive frame is coupled to the substrate,
wherein the first chip and the conductive frame have a height that is substantially the same,
wherein a remainder of the substrate surface is covered in a layer of encapsulation material having the same height as the first chip and the conductive frame;
a second chip positioned on a first portion of the first chip surface,
wherein the second chip is positioned to expose at least one exposed portion of the first chip surface,
wherein the at least one exposed portion comprises at least one of the plurality of thermal vias; and
at least one conductive plate positioned on the at least one exposed portion,
wherein the conductive plate is coupled to the conductive frame and the at least one of the plurality of thermal vias.

2. The chip package of claim 1, wherein the conductive frame comprises a copper layer.

3. The chip package of claim 1, wherein the conductive frame comprises a plurality of tin-silver (SnAg) solder composites.

4. The chip package of claim 1, wherein the conductive frame comprises a plurality of nano particle composites.

5. The chip package of claim 4, wherein the plurality of nano particle composites comprise carbon nano tube composites.

6. The chip package of claim 1, wherein the conductive frame comprises a distance from the first chip.

7. The chip package of claim 6, wherein the distance from the first chip comprises a range from 100 μm to approximately 2 mm.

8. The chip package of claim 1, wherein the at least one conductive plate comprises a distance from the second chip.

9. The chip package of claim 8, wherein the distance from the second chip comprises a range from 25 μm to approximately 2 mm.

10. The chip package of claim 1, wherein the second chip is positioned perpendicular relative to the first chip.

11. A method of forming a chip package comprising:
electrically coupling a first conductive frame on a package substrate, wherein the first conductive frame comprises a first frame opening;
positioning a first chip within the first frame opening and electrically coupling the first chip on the package substrate,
wherein the first chip comprises a first orientation;
electrically coupling at least one conductive plate to the first conductive frame and a top surface of the first chip,
wherein the at least one conductive plate is positioned to leave an exposed portion of the top surface of the first chip; and
electrically coupling a bottom surface of a second chip to the top surface of the first chip,
wherein the second chip comprises a second orientation different than the first orientation.

12. The method of claim 11, wherein the conductive frame comprises a copper layer.

13. The method of claim 11, wherein the conductive frame comprises a plurality of tin-silver (SnAg) solder composites.

14. The method of claim 11, wherein the conductive frame comprises a plurality of nano particle composites.

15. The method of claim 14, wherein the plurality of nano particle composites comprise carbon nano tube composites.

16. The method of claim 11, wherein the conductive frame comprises a distance from the first chip.

17. The method of claim 16, wherein the distance from the first chip comprises a range from 100 μm to approximately 2 mm.

18. The method of claim 11, wherein the at least one conductive plate comprises a distance from the second chip.

19. The method of claim 18, wherein the distance from the second chip comprises a range from 25 μm to approximately 2 mm.

20. The method of claim 11, wherein the second chip is positioned perpendicular relative to the first chip.
